(19) United States
(12) Patent Application Publication
(10) Pub. No.: US 2014/0241462 A1
(43) Pub. Date: Aug. 28, 2014

(54) CIRCUIT AND METHOD FOR ENVELOPE TRACKING AND ENVELOPE-TRACKING TRANSMITTER FOR RADIO-FREQUENCY TRANSMISSION

(71) Applicant: NVIDIA CORPORATION, Santa Clara, CA (US)

(72) Inventors: Abdellatif Bellaouar, Richardson, TX (US); Arul Balasubramaniyan, Richardson, TX (US); Imtinan Elahi, Richardson, TX (US)

(73) Assignee: Nvidia Corporation, Santa Clara, CA (US)

(21) Appl. No.: 13/863,810

(22) Filed: Apr. 16, 2013

Related U.S. Application Data
(60) Provisional application No. 61/769,424, filed on Feb. 26, 2013.

(51) Int. Cl. H03F 1/32; H03G 3/20

(52) U.S. Cl. CPC H03F 1/3241; H03G 3/20
USPC 375/297

(57) ABSTRACT

A method of envelope tracking and an envelope tracking (ET) circuit. One embodiment of the (ET) circuit is for radio frequency (RF) transmission and includes: (1) an amplitude calculator configured to generate an amplitude signal that approximates the amplitude of an input signal, (2) a peak detector configured to take samples of the amplitude signal within a time window and produce an envelope signal that represents an amplitude peak among the samples, and (3) a signal conditioner configured to condition the envelope signal for driving a power supply input stage of a power amplifier operable to amplify and transmit an RF signal based on the input signal.

### CROSS-REFERENCE TO RELATED APPLICATION

This application claims the benefit of U.S. Provisional Application Ser. No. 61/769,424, filed by Bellaouar, et al., on Feb. 26, 2013, entitled “Method of Power Amplifier Efficiency Improvement Using Sampled Envelope Technique,” commonly assigned with this application and incorporated herein by reference.

### TECHNICAL FIELD

This application is directed, in general, to radio frequency (RF) transmitters and, more specifically, to envelope tracking (ET) technology for power amplifiers used in RF transmitters.

### BACKGROUND

RF power amplifiers are used in RF transmitters to convert low-power RF signals into higher-power signals, typically for driving antennas. Transmitted RF signals are typically modulated according to some modulation scheme, and a resulting modulated waveform, over time, has a peak amplitude and a root-mean-square amplitude, among other characteristics. A ratio of the squares of these two characteristics is known as the peak-to-average power ratio (PAPR) and is a comparison of the waveform peak power and average power. Conventional power amplifiers, supplied by a constant supply voltage, operate most efficiently at peak power, or at a low PAPR. As the waveform's PAPR increases, the power amplifier spends more time operating below peak power and below maximum efficiency. Excess power (waste) is generally dissipated from the RF transmitter as heat, which frequently requires further power consumption in the form of cooling components.

Demands on RF systems are on the rise. Modern systems are called upon to support higher data rates over tightening bandwidth. Furthermore, the proliferation of RF devices has led to demand for support across multiple frequency bands. New bands of the frequency spectrum are continually released to meet capacity demands. Each of these factors has led to increased power consumption in RF transmitters, and specifically, increased power demands and decreased efficiency in power amplifiers. As demands have grown, so too has RF technology. For example, the evolution of 3G, 4G and long term evolution (LTE) communication networks have led to significant increases in RF signal dynamic range and increased peak power to accommodate higher data rates and more complex modulation schemes. The availability of varieties of channel coding and modulation techniques, the demand for broader channel bandwidths, and high PAPR modulation schemes all press their demands on power availability and efficiency.

ET has been introduced to power amplifiers to ensure the power amplifier operates at peak efficiency for any given instantaneous output power requirement. With ET, the power amplifier supply voltage is reduced from its maximum value to track the “envelope” of the RF signal, thereby reducing the energy dissipated as heat.

### SUMMARY

One aspect provides an envelope tracking (ET) circuit for radio frequency transmission, including: (1) an amplitude calculator configured to generate an amplitude signal that approximates the amplitude of an input signal, (2) a peak detector coupled to the amplitude calculator and configured to take samples of the amplitude signal within a time window and produce an envelope signal that represents an amplitude peak among the samples, and (3) a signal conditioner coupled to the peak detector and configured to condition the envelope signal for driving a power supply input stage of a power amplifier operable to amplify and transmit an RF signal based on the input signal.

Another aspect provides a method of envelope tracking, including: (1) sampling amplitude data, calculated from an input signal, over a time window and identifying an amplitude peak within the time window, (2) generating a DC signal correlating to the amplitude peak that is scaled to match the power scaling of an RF signal based on the input signal, and (3) conditioning the DC signal for supplying power to a power amplifier configured to amplify the RF signal for subsequent transmission.

Yet another aspect provides an ET transmitter for RF transmission, including: (1) an RF integrated circuit (RFIC) configured to generate an RF signal based on an input I/Q data signal, (2) a power amplifier having an RF input stage and a power supply input stage, and configured to amplify the RF signal for subsequent transmission, and (3) an ET power controller. In one embodiment, the ET power controller is configured to: (3a) sample amplitude data of the input I/Q data signal over a series of time windows, (3b) detect respective amplitude peaks within the series of time windows and generate an envelope signal based on the respective amplitude peaks, and (3c) adjust the gain of the envelope signal to match that of the RF signal and apply a digital-to-analog converter (DAC) and smoothing filter to condition the envelope signal for driving the power supply input stage of the power amplifier.

### BRIEF DESCRIPTION

Reference is now made to the following descriptions taken in conjunction with the accompanying drawings, in which:

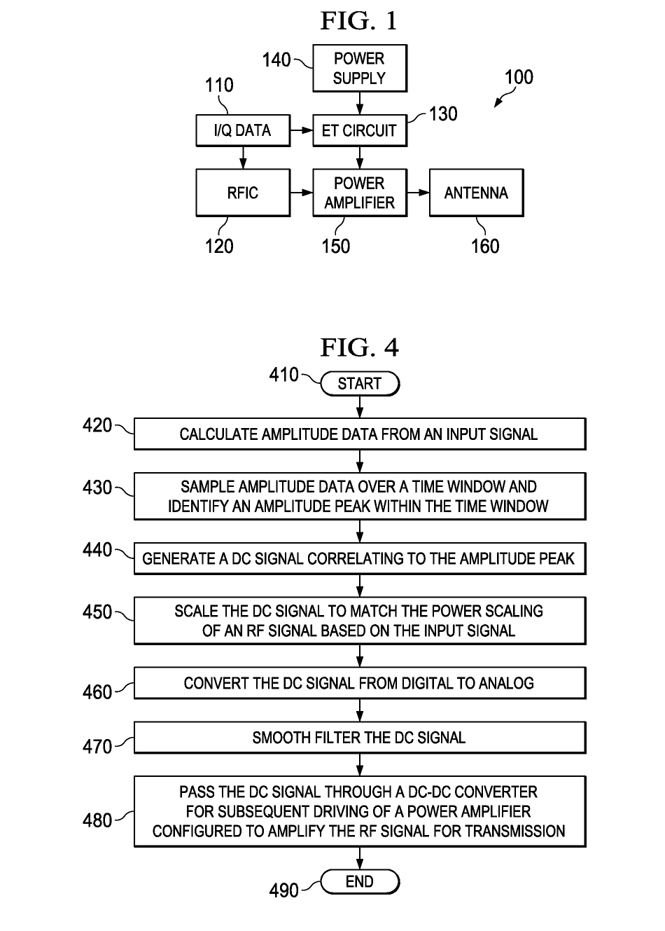

FIG. 1 is a block diagram of an RF transmitter within which the ET circuit and method of ET introduced herein may be embodied or carried out;

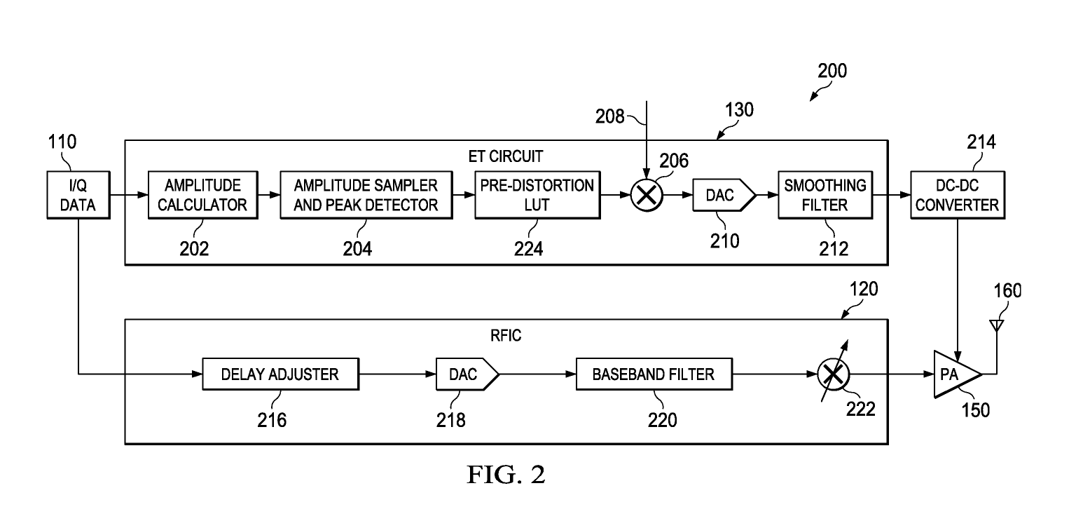

FIG. 2 is a functional block diagram of one embodiment of an ET RF transmitter;

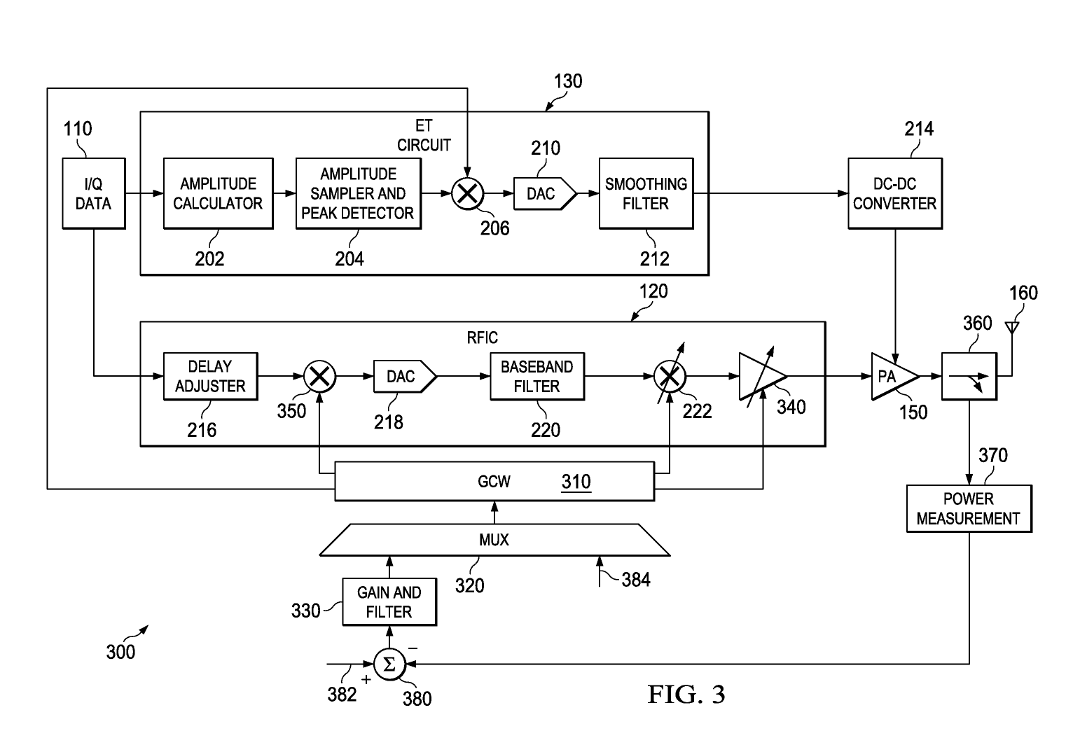

FIG. 3 is a functional block diagram of another embodiment of an ET RF transmitter with a closed-loop gain control; and

FIG. 4 is a flow diagram of one embodiment of a method of ET.

### DETAILED DESCRIPTION

Basic envelope tracking for a waveform starts with a stream of I/Q data, which is an X-Y representation of the magnitude and phase data of the waveform. The I/Q data is used in an RF integrated circuit (RFIC) to generate an RF signal to drive a power amplifier and ultimately be transmitted. An RFIC, in the context of an RF transmitter, generally includes a digital-to-analog converter (DAC) to convert the digital I/Q data into an analog waveform. That waveform would then be passed through a baseband filter and then up-converted to a carrier frequency for transmission. At that point, the RFIC has generated the RF signal that ultimately is amplified by the power amplifier.

An envelope is generated from the I/Q data, generally based on the amplitude of the waveform. Rather than using a fixed power supply, such as a battery, to power the power amplifier, the envelope is used in combination with a power supply. One configuration could modulate the envelope onto the power supply output, the result being a modulated supply signal tracking the envelope.

Envelope tracking circuits typically employ a variety of other components to filter, offset, adjust gain or perform other processing on the envelope to improve its condition for supplying the power amplifier. These components should generally have a large bandwidth to support high-frequency, high-data rate communication, for instance, LTE 10-20 MHz. Some ET circuits use a DC-DC converter to supply the power amplifier. Any DC-DC converter in the ET circuit should operate at a fast switching speed to handle fast changes in amplitude. It is common in ET circuits to use a DAC and a filter to condition the envelope signal. These devices should be high-speed and low-noise. There are also a variety of other implications of ET circuits in high-frequency, high-data rate transmitters with respect to noise, including mitigating transmitted noise by making the receiver less sensitive to noise (desensing) and reducing the capacitance at the supply stage of the power amplifier, which lowers the power amplifier's power supply rejection ratio (PSRR).

It is realized herein that an ET circuit can be made that relaxes the constraints on bandwidth and, consequently, limits transmitted noise and relaxes the speed requirement of the DC-DC converter. The ET circuit should achieve similar power efficiency at the power amplifier.

It is realized herein the amplitude data can be sampled over a series of time windows. These windows can be on the order of nanoseconds (ns), for example, 200 ns. The sampling rate defines the number of samples in a given time window, from which, it is realized herein, a peak amplitude can be determined. If, for example, the sampling rate is 20 samples per time window, 20 amplitude samples are evaluated and a maximum for the given time window is found. The output of amplitude sampling and peak detection is a DC voltage level, or envelope signal, for each time window. It is realized herein that a lookup table (LUT) may be used to scale the DC voltage level. This scaling allows the ET circuit to recognize compression in the power amplifier and to correct power amplifier gain distortion due to changes in the supply. The LUT optionally employed is sometimes referred to as a pre-distortion LUT. Application of the LUT can be carried out before or after amplitude sampling and peak detection.

The output for the series of time windows forms an envelope signal, which is ultimately used to supply the power amplifier. The envelope signal is then scaled to match the scaling of the RF signal. There are a variety of approaches to achieve the scaling, including use of a closed-loop power control circuit. Another option is to “tie” scaling factors of the ET circuit to those of the RFIC. Gains can be applied at various points in the ET circuit and RFIC. In the ET circuit, gain can be applied before or after amplitude sampling and peak detection, or possibly both.

The envelope signal also undergoes conditioning before supplying the power amplifier. The envelope signal can be passed through a DAC and then smooth filtered to shape the envelope signal. The envelope signal may also be digitally filtered prior to the DAC. The envelope signal can then be used to drive the DC-DC converter, which supplies the power amplifier. It is realized herein this envelope signal does not demand the large bandwidth that is common in conventional ET circuits. The DC-DC converter can be lower bandwidth and the switching speed relaxed. Consequently, it is realized herein, the DC-DC converter can filter quantization noise, thermal noise, spurs and other noise generated by the ET circuit. It is further realized herein it is unnecessary to reduce the capacitance at the supply stage of the power amplifier, allowing for improved PSRR.

In the RFIC, it is typically necessary to introduce a delay element to ensure the RF signal reaching the power amplifier is synchronized appropriately with the envelope signal, from the ET circuit, supplying the power amplifier. For example, I/Q data driving the RFIC can be delayed to align with the delay in the ET circuit. Alternatively, delay elements may be necessary in the ET circuit, or possibly in both the ET circuit and the RFIC. Delay adjustments can be had by a variety of devices, including integer delays and fractional delays.

It is realized herein the ET circuit can be combined with a closed-loop power control circuit to manage the various gains applied in the ET circuit and RFIC. The purpose of the various gains is to ensure the envelope signal from the ET circuit is scaled to match that of the RF signal from the RFIC. Additionally, it is realized herein, a DC offset voltage can be applied to the envelope signal before or after any conditioning is carried out, which includes any DAC, filter, or DC-DC converter.

Before describing various embodiments of the ET circuit or method of ET introduced herein, an RF transmitter within which the ET circuit or method of ET may be embodied or carried out will be described.

FIG. 1 is a block diagram of an RF transmitter 100. Transmitter 100 includes I/Q data 110, an RFIC 120, an ET circuit 130, a power supply 140, a power amplifier 150 and an antenna 160. I/Q data 110 is the digital source data from which RFIC 120 generates an analog waveform that is baseband-filtered and up-converted to an RF signal. That RF signal is ultimately amplified to a much larger powered RF signal by power amplifier 150 and transmitted by antenna 160.

ET circuit 130 uses I/Q data 110 to generate the envelope of the waveform generated by RFIC 120. The envelope signal is then conditioned and used in combination with power supply 140 to supply power to power amplifier 150 such that the supply tracks the envelope and the efficiency of power amplifier 150 improves.

Having described an RF transmitter within which the ET circuit or method of ET may be embodied or carried out, various embodiments of the ET circuit and method will be described.

FIG. 2 is a functional block diagram of one embodiment of an ET RF transmitter 200. Transmitter 200 includes I/Q data 110, RFIC 120, ET circuit 130, power amplifier 150 and antenna 160, all from FIG. 1. Transmitter 200 also includes a DC-DC converter 214. In this embodiment, RFIC includes a delay adjuster 216, a DAC 218, a baseband filter 220 and an RF mixer 222. I/Q data 110 is delayed by delay adjuster 216 such that it aligns with the envelope signal generated in ET circuit 130 and ultimately employed in supplying power amplifier 150. The delayed I/Q data is converted to an analog waveform by DAC 218. The analog waveform is passed through baseband filter 220 and up-converted to a carrier frequency by RF mixer 222. The resulting RF signal is what gets amplified by power amplifier 150 and transmitted by antenna 160.

ET circuit 130 includes an amplitude calculator 202, an amplitude sampler and peak detector 204, a pre-distortion LUT 224, a multiplier 206, a DAC 210 and a smoothing filter 212. Amplitude calculator 202 uses I/Q data 110 to approximate the amplitude of the waveform. There are numerous methods available for making this approximation, including linear amplitude approximation and iterative algorithms, such as those available in a coordinate rotation digital computer (CORDIC).

Amplitude sampler and peak detector 204 samples the amplitude data and detects a peak amplitude in a group of samples over a period of time, or the time window. The amplitude data is divided into a series of time windows, for each of which a peak amplitude is determined. Both the duration of the time window and the number of samples in each time window are configurable, and together establish a sampling rate. The output of amplitude sampler and peak detector 204 is an envelope signal, or a series of DC voltage levels corresponding to the peak amplitude for each time window. This may also be referred to as an “envelope” signal.

The envelope signal is then processed by pre-distortion LUT 224. Power amplifier 150 should ideally perform linearly, but has inherent nonlinearities. These nonlinearities manifest as gain distortion and can make the power amplifier less power efficient. This gain distortion is commonly referred to as gain compression, which is a reference to the reduced output when operating outside the device's linear region, or operating “in compression.” The implicit supply changes carried out by ET circuit 130 potentially exacerbate the problem by driving the supply of power amplifier 150 into and out of the linear region. Pre-distortion LUT 224 maps a non-linear gain curve that countervails the non-linear response of power amplifier 150, yielding a consistently linear gain curve for power amplifier 150. Alternatively, LUT 224 can be implemented to always drive power amplifier 150 in compression.

Multiplier 206 adjusts the gain of the envelope signal according to a gain control signal 208, such that the scaling of the envelope signal matches the power scaling of the RF signal from RFIC 120. DAC 210 then converts the envelope signal to analog, where it is passed through smoothing filter 212. The “conditioned” envelope signal then drives DC-DC converter 214, which supplies power to power amplifier 150.

FIG. 3 is a functional block diagram of another embodiment of an ET RF transmitter 300 having a close-loop gain control circuit. Transmitter 300 includes I/Q data 110, RFIC 120, ET circuit 130, power amplifier 150 and antenna 160, all from FIG. 1. Transmitter 300 also includes DC-DC converter 214 from FIG. 2, in addition to a coupler 360, a power measurement device 370, a summer 380, a gain and filter device 330 and a multiplexer 320. An amplified RF signal is produced by power amplifier 150 and passes through coupler 360. Coupler 360 passes most of the amplified RF signal on to antenna 160 for transmission, while a portion of the signal is fed back to power measurement device 370. Measured power is compared to a reference level, or power control signal 382, by summer 380. The difference passes through gain and filter module 330 before reaching multiplexer 320. Multiplexer 320 selects between a closed-loop gain control circuit and an open-loop gain control 384. The output of multiplexer 320 is a gain control word (GCW) 310. GCW 310 specifies respective gains throughout ET circuit 130 and RFIC 120.

RFIC 120 includes delay adjuster 216, DAC 218, baseband filter 220 and RF mixer 222, all of FIG. 2. In addition, RFIC 120 includes a digital multiplier 350 and a digital variable gain amplifier (DVGA) 340. Digital multiplier 350 applies a gain according to GCW 310 to I/Q data 110. DVGA 340 applies a gain according to GCW 310 to the up-converted RF signal. In certain embodiments, additional gain is applied to the output of baseband filter 220.

ET circuit 130 includes amplitude calculator 202, amplitude sampler and peak detector 204, multiplier 206, DAC 210, and smoothing filter 212, all of FIG. 2. Multiplier 206 applies a gain according to GCW 310 to the envelope signal generated by amplitude sampler and peak detector 204. In alternate embodiments, a gain can be applied to the amplitude data from amplitude calculator 202 before sampling and peak detection.

FIG. 4 is a flow diagram of one embodiment of a method of ET. The method begins in a start step 410. In a step 420 amplitude data is calculated from a digital input signal. The amplitude data from step 420 is sampled over a time window in a step 430. A peak amplitude is then detected within the time window. In a step 440, an envelope signal, is generated that correlates to the peak amplitude. The DC signal is then scaled in a step 450 to match the power scaling of an RF signal generated by an RFIC based on the digital input signal from step 420. The scaled envelope signal is converted from digital to analog in a step 460 and smooth filtered in a step 470. The conditioned DC signal drives a DC-DC converter in a step 480. The DC-DC converter supplies power to a power amplifier that is configured to amplify the RF signal from the RFIC for ultimate transmission. The method ends in an end step 490.

Those skilled in the art to which this application relates will appreciate that other and further additions, deletions, substitutions and modifications may be made to the described embodiments.

What is claimed is:

1. An envelope tracking (ET) circuit for radio frequency transmission, comprising:
an amplitude calculator configured to generate an amplitude signal that approximates the amplitude of an input signal;
a peak detector coupled to said amplitude calculator and configured to take samples of said amplitude signal within a time window and produce an envelope signal that represents an amplitude peak among said samples; and
a signal conditioner coupled to said peak detector and configured to condition said envelope signal for driving a power supply input stage of a power amplifier operable to amplify and transmit an RF signal based on said input signal.

2. The ET circuit recited in claim 1 wherein said signal conditioner includes:
a gain controller configured to adjust the gain of said envelope signal to that of said RF signal;
a digital-to-analog converter (DAC) coupled to said gain controller; and
a smoothing filter coupled to said DAC.

3. The ET circuit recited in claim 1 further comprising a pre-distortion lookup table (LUT) configured to adjust said envelope signal to mitigate gain distortion introduced by said power amplifier.

4. The ET circuit recited in claim 1 wherein said amplitude calculator employs a linear amplitude approximation algorithm.

5. The ET circuit recited in claim 1 wherein said samples are taken at a rate of 20 samples per time window and said time window is 250 nanoseconds (ns).

6. The ET circuit recited in claim 1 wherein said input signal is an I/Q data signal.

7. The ET circuit recited in claim 1 further comprising an adjustable delay module coupled serially with said amplitude calculator and said peak detector, and operable to ensure said envelope signal is synchronized with said RF signal.

8. The ET circuit recited in claim 1 further comprising a digital filter through which said envelope signal passes before reaching said signal conditioner.

9. A method of envelope tracking, comprising:
sampling amplitude data, calculated from an input signal, over a time window and identifying an amplitude peak within said time window;
generating a DC signal correlating to said amplitude peak that is scaled to match the power scaling of an RF signal based on said input signal; and
conditioning said DC signal for supplying power to a power amplifier configured to amplify said RF signal for subsequent transmission.

10. The method recited in claim 9 further comprising employing a pre-distortion lookup table (LUT) to adjust said envelope signal to mitigate gain distortion introduced by said power amplifier.

11. The method recited in claim 9 further comprising calculating said amplitude data and applying a gain to the resulting amplitude signal.

12. The method recited in claim 9 further comprising delaying said RF signal such that said DC signal is synchronized with said RF signal upon arrival at said power amplifier.

13. The method recited in claim 9 wherein said conditioning includes:
converting said DC signal from digital to analog;
smooth filtering said DC signal; and
passing said DC signal through a DC-DC converter for subsequent supplying of power to said power amplifier.

14. The method recited in claim 9 further comprising applying a DC offset to said DC signal prior to said conditioning.

15. The method recited in claim 9 further comprising applying a DC offset to said DC signal after said conditioning.

16. The method recited in claim 9 further comprising filtering said DC signal prior to said conditioning.

17. An envelope tracking (ET) transmitter for radio frequency (RF) transmission, comprising:
an RF integrated circuit (RFIC) configured to generate an RF signal based on an input I/Q data signal;
a power amplifier having an RF input stage and power supply input stage, and configured to amplify said RF signal for subsequent transmission; and
an ET power controller configured to:
sample amplitude data of said input I/Q data signal over a series of time windows,
detect respective amplitude peaks within said series of time windows and generate an envelope signal based on said respective amplitude peaks, and
adjust the gain of said envelope signal to match that of said RF signal and apply a digital-to-analog converter (DAC) and smoothing filter to condition said envelope signal for driving said power supply input stage of said power amplifier.

18. The ET transmitter recited in claim 17 wherein said RFIC includes:
a digital-to-analog converter (DAC) configured to convert said input I/Q data signal to an analog signal;
a baseband filter coupled to said DAC and configured to pass a baseband signal upon application to said analog signal; and
an RF mixer coupled to said baseband filter and operable to adjust the frequency of said baseband signal to that of said RF signal.

19. The ET transmitter recited in claim 17 further comprising a closed-loop power control circuit configured to match said gain of said envelope signal and the gain of said RF signal based on a measured power of said RF signal that is translated to a gain control signal that is employed by said ET power controller and said RFIC.

20. The ET transmitter recited in claim 17 further comprising an adjustable delay module serially coupled to an input stage of said RFIC and operable to delay said input I/Q data signal such that said RF signal and said envelope signal are synchronized upon arrival at said power amplifier.

21. The ET transmitter recited in claim 17 further comprising a pre-distortion lookup table (LUT) configured to correct gain distortion manifest in said envelope signal.

22. The ET transmitter recited in claim 17 further comprising a DC-to-DC converter serially coupled between an output stage of said ET power controller and said power supply input stage of said power amplifier, and configured to power said power amplifier according to said envelope signal.
